(19) United States
(12) Patent Application Publication
(10) Pub. No.: US 2026/0260644 A1
(43) Pub. Date: Sep. 3, 2026

(54) METHOD AND SYSTEM FOR GENERATING MOTION SOUND OF A MOVING VIRTUAL INDUSTRIAL DEVICE

(71) Applicant: Siemens Industry Software Ltd., Tel Aviv (IL)

(72) Inventor: Moshe Hazan, Elad (IL)

(21) Appl. No.: 18/842,503

(22) PCT Filed: Mar. 22, 2022
(86) PCT No.: PCT/IB2022/052589

§ 371 Date: Aug. 29, 2024

(51) Int. Cl. G10K 15/04

(52) U.S. Cl. CPC G10K 15/04

(57) ABSTRACT

Systems and a method for generating motion sound of a moving virtual industrial device. Data on a location of a virtual receiver are received. Data on a virtual device for which motion sound is to be generated are received. Data on a motion task of the device are received; the motion task data includes data on a source location and data on a target location. A device sound simulator is applied to the input data to obtain output motion sound simulating the motion sound of the virtual device moving between the source location and the target location. The motion sound detected at the receiver's location is determined by processing the output motion sound with differential position data based on the mutual position between the virtual device and the virtual receiver.

### TECHNICAL FIELD

The present disclosure is directed, in general, to computer-aided design, visualization, and manufacturing (“CAD”) systems, product lifecycle management (“PLM”) systems, product data management (“PDM”) systems, production environment simulation, and similar systems, that manage data for products and other items (collectively, “Product Data Management” systems or PDM systems). More specifically, the disclosure is directed to production environment simulation.

### BACKGROUND OF THE DISCLOSURE

Software applications for industrial robotic simulation are used for validation, optimization and virtual commissioning purposes.

Examples of such robotic simulation platforms and systems include, but are not limited to, Computer Assisted Robotic (“CAR”) tools, Process Simulate (a product of the Siemens Group), robotic software simulations tools, software applications for industrial robotic simulation and other systems and virtual stations for industrial robotic simulation.

A robotic simulation platform enables simulation engineers to simulate robotic operations performed by multiple industrial robots on a simulated scene of the shop floor. Robotic simulation platforms enable simulating the industrial activities of robots and of other moving industrial devices in a factory.

With Virtual reality (“VR”) and augmented reality (“AR”) tools, CAR systems allow users to see the robotic factory in a realistic size and they get the VR/AR experience of visiting the real factory.

The professionals working in robotic factories are accustomed to the sounds produced by the factory robots and by other moving devices during their manufacturing operations.

Current CAR systems and their VR/AR tools do not provide users with industrial device sounds realistically simulating the sound of the moving industrial devices. Improved techniques for simulating industrial sounds are desirable.

### SUMMARY OF THE DISCLOSURE

Various disclosed embodiments include methods, systems, and computer readable mediums for generating motion sound of a moving virtual industrial device; the sound being detectable by a virtual receiver positioned at a location within a virtual environment of an industrial simulation comprising a plurality of moving virtual devices. A method includes receiving data on a location of a virtual receiver. The method includes receiving data on a virtual device for which motion sound is to be generated. The method includes receiving input data on a motion task of the device whereby device's motion task data comprises data on a source location and data on a target location. The method includes applying to the input data a device sound simulator to obtain output motion sound simulating the motion sound of the virtual device moving between the source location and the target location. The method includes determining the motion sound detected at the receiver's location by processing the output motion sound with differential position data based on the mutual position between the virtual device and the virtual receiver.

Various disclosed embodiments include methods, systems, and computer readable mediums a trained function for generating motion sound of a moving virtual industrial device. A method includes receiving input training data; wherein the input training data comprise data on a motion task of the device comprising data on a source location and data on a target location. The method includes receiving output training data; wherein the output training data comprise data on output motion sounds of the industrial device moving between the source location and the target location; wherein the output training data is related to the input training data. The method includes training a function based on the input training data and the output training data via a Machine Learning (“ML”) algorithm. The method includes providing the trained function for modeling a device sound simulator.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 illustrates a block diagram of a data processing system in which an embodiment can be implemented.

FIG. 2 illustrates a flowchart for generating motion sound of a moving virtual industrial device in accordance with embodiments.

FIG. 3 schematically illustrates a block diagram for generating motion sound of three moving robots in accordance with embodiments.

FIG. 4 schematically illustrates motion tasks data of a robot in in accordance with embodiments.

FIG. 5 schematically illustrates motion tasks data of joints of a robot in accordance with embodiments.

FIG. 6 schematically illustrates a block diagram for generating motion sound of a moving device in accordance with embodiments.

FIG. 7 schematically illustrates a block diagram for training a device sound simulator in accordance with embodiments.

FIG. 8 schematically illustrates a block diagram for generating a sound simulator based on a mapping table in accordance with embodiments.

### DETAILED DESCRIPTION

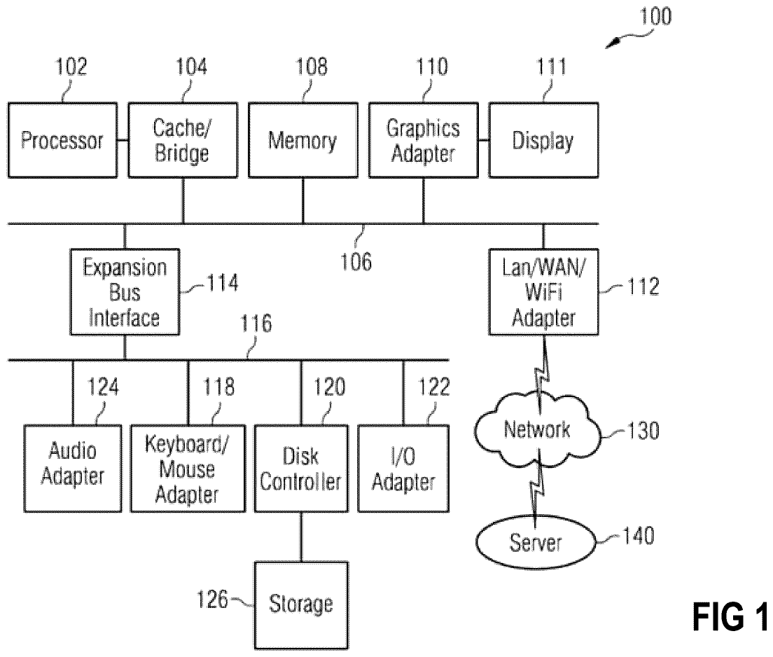

FIGS. 1 through 8, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Features, advantages, or alternative embodiments herein can be assigned to the other claimed objects and vice versa. Furthermore, in the following the solution according to the embodiments is described with respect to methods and systems for generating motion sound of a moving virtual industrial device as well as with respect to methods and systems for providing a trained function for generating motion sound of a moving industrial device. Features, advantages, or alternative embodiments herein can be assigned to the other claimed objects and vice versa.

Previous techniques did not enable to realistically generated motion sounds of moving virtual industrial devices.

The embodiments disclosed herein provide numerous technical benefits, including but not limited to the following examples.

Embodiments provide simulation users with the industrial “feel” experience to accompany the industrial “look” experience already known for industrial simulation systems.

Embodiments provide to users the same “look and feel” as in the real robotic factory.

Embodiments enable generating industrial sounds via Artificial Intelligence for improving the user experience of simulation users, especially while they are utilizing VR and/or AR tools.

Embodiments enable a VR system to play the virtual sounds of robotic tasks which realistically reflect the real factory sound.

Embodiments enable generating of moving industrial devices in simulated environments.

Embodiments enable generating industrial sound perceivable by a virtual receiver based on data from the industrial simulation.

Embodiments enable to pick a point in a simulation scene and determine the sound receivable at that picked point.

Embodiments enable industrial professionals to realistically inspect an industrial simulation and perform the necessary adjustments to the industrial simulation for validation, optimization and virtual commissioning purposes. In embodiments, the performed simulation adjustments in the virtual environment are in turn performed in the real industrial environment.

FIG. 1 illustrates a block diagram of a data processing system 100 in which an embodiment can be implemented, for example as a PDM system particularly configured by software or otherwise to perform the processes as described herein, and in particular as each one of a plurality of interconnected and communicating systems as described herein. The data processing system 100 illustrated can include a processor 102 connected to a level two cache/bridge 104, which is connected in turn to a local system bus 106. Local system bus 106 may be, for example, a peripheral component interconnect (PCI) architecture bus. Also connected to local system bus in the illustrated example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (I/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but are not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, touchscreen, etc.

Those of ordinary skill in the art will appreciate that the hardware illustrated in FIG. 1 may vary for particular implementations. For example, other peripheral devices, such as an optical disk drive and the like, also may be used in addition or in place of the hardware illustrated. The illustrated example is provided for the purpose of explanation only and is not meant to imply architectural limitations with respect to the present disclosure.

A data processing system in accordance with an embodiment of the present disclosure can include an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

LAN/WAN/Wireless adapter 112 can be connected to a network 130 (not a part of data processing system 100), which can be any public or private data processing system network or combination of networks, as known to those of skill in the art, including the Internet. Data processing system 100 can communicate over network 130 with server system 140, which is also not part of data processing system 100, but can be implemented, for example, as a separate data processing system 100.

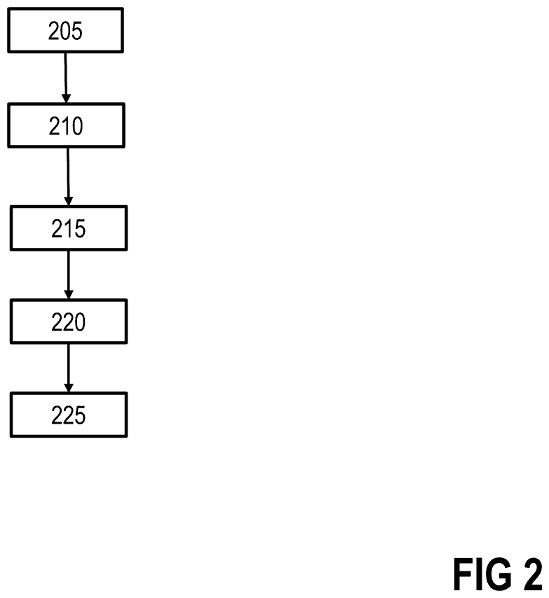

FIG. 2 illustrates a flowchart of a method for generating motion sound of a moving virtual industrial device in accordance with disclosed embodiments. Such method can be performed, for example, by system 100 of FIG. 1 described above, but the “system” in the process below can be any apparatus configured to perform a process as described.

As used herein the term industrial device denotes any industrial object whose motion produces a sound detectable by a human position at a receiver location. Examples of industrial devices include robots, conveyors, turn tables, sub-units of complex industrial devices e.g. joints of robots, kinematic elements of a kinematic device and other types of industrial moving devices.

The motion sound is detectable by a virtual receiver positioned at a location within a virtual environment of an industrial simulation comprising a plurality of moving virtual devices.

At act 205, data on a location of a virtual receiver are received. In embodiments, the receiver location may be obtained via a VR/AR tool. In embodiments, the receiver location is obtained by a selection within the virtual environment, e.g. a manual selection or automatic selection of a prescribed location in the virtual space.

At act 210, data on a virtual device for which motion sound is to be generated are received. Examples of virtual device data include, but are not limited to, type of industrial device, its model and vendor, type of tool, type of operation and process to be performed by the device.

At act 215, input data are received. The input data comprise data a motion task of the device; said device's motion task data comprising data on a source location and data on a target location. In embodiments, the device motion task data are preferably received by the simulation system.

At act 220, to the input data a device sound simulator is applied to obtain output motion sound simulating the motion sound of the virtual device moving between the source location and the target location. In embodiments, other sounds of the device may be added depending on inputted device operation data. As used here in the term “device operation” or simply “operation” denotes a type of industrial process performed by the device. Examples of device operations include, but are not limited to, welding, laser cutting, water jetting and other noisy operations performed by the industrial device.

At act 225, the motion sound detected at the receiver's location is determined by processing the output motion sound with differential position data based on the mutual locations between the virtual device and the virtual receiver. In embodiments, differential position data includes distance between the receiver's location and the industrial device location, and data on any obstacles present in the virtual space between the receiver's location and the virtual industrial device location which have an impact on the detected sounds. In embodiments, differential position data are received by the simulation system.

In embodiments, a user by hearing the detected motion sound performs a change in the virtual space of the simulation whereby the performed change is applied in the real industrial environment.

In embodiments, the device sound simulator may be configured to output simulation motion sound by heuristically selecting a motion sound based on a stored motion sound depending on the received input data for example stored in a mapping table. The stored motion sound may be obtained from a recorded motion sound or via a synthetic sound which are stored in a sound module comprising a fixed mapping table which is accessible via a heuristic function.

In embodiments, the device sound simulator may be obtained by a function trained via a Machine Learning algorithm.

In embodiments, acts 210-225 may be performed for a set of moving virtual devices and a combined industrial sound at a receiver location is computed as a combination of the set of determined corresponding devices' motion sounds.

In embodiments, for the input data, the data of the source S and target T may conveniently be selected from the group consisting of:
S/T coordinate location, S/T motion parameters and S/T device's configuration;
S/T coordinate location, and S/T device's configuration;
S/T device's pose and S/T motion parameters;
S/T device's pose.

In embodiments, the sound simulator may advantageously be device-specific and the device may be selected from the group consisting of:
a generic robot;
a robot of a specific type;
a robot without a tool;
a robot with a tool;
a turn table;
a conveyor;
a joint of a robot;
a kinematic element of a kinematic device.

In embodiments, a trained function for generating motion sound of a moving virtual industrial device is provided by:
receiving input training data; wherein the input training data comprise data motion tasks of the device; said device's motion task data comprising data on a source location and data on a target location;
receiving output training data; wherein the output training data comprise data on output motion sounds of the industrial device moving between the source location and the target location; wherein the output training data is related to the input training data;
training a function based on the input training data and the output training data via a Machine Learning algorithm;
providing the trained function for modeling an industrial sound simulator.

Of course, those of skill in the art will recognize that, unless specifically indicated or required by the sequence of operations, certain steps in the processes described above may be omitted, performed concurrently or sequentially, or performed in a different order.

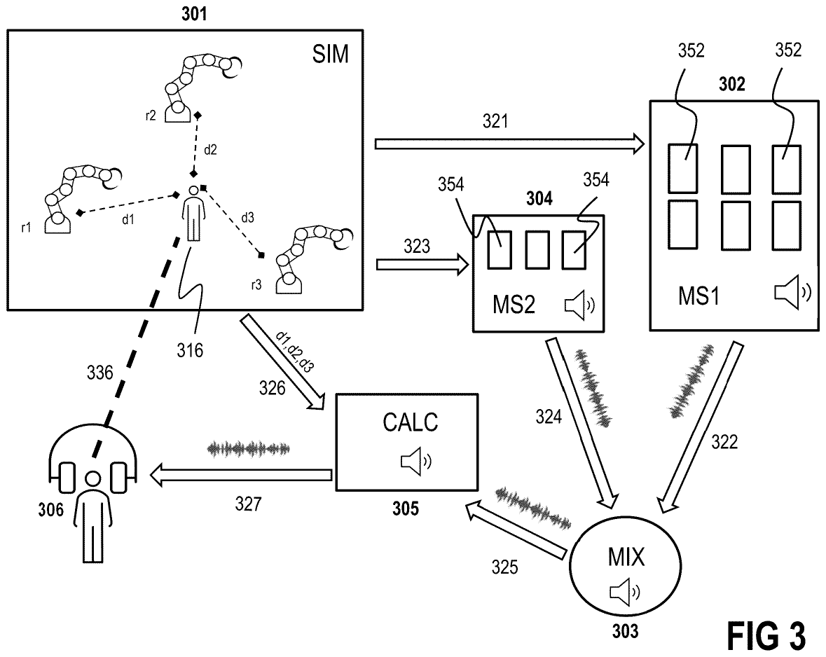

FIG. 3 schematically illustrates a block diagram for generating motion sound of three moving robots in accordance with embodiments.

A simulation platform—e.g. a CAR system like Process Simulate a software product of the Siemens group—simulate a virtual environment of a robotic factory 301 comprising three robots r1, r2, r3.

A receiver location is the location of a virtual user 316 in the virtual environment. In embodiments, the location of the virtual receiver 316 in the digital factory is determined by manual selection 336 or by automatic selection of a corresponding location in the virtual environment. In other embodiments, the location of the virtual receiver is obtained 336 from a VR and/or AR tool (not shown) utilized by the real user 306. In summary, the receiver location 316 reflects 336 the VR/AR tool position of the real user 306 can be moved via VR or by picking/selecting it directly on the CAR tool-manual selection 336 or automatically predetermined (not shown).

With embodiments, the real user 306 is provided with industrial sounds 327 realistically emulating the moving devices of the digital factory 301 depending on his/her virtual position 316 in the simulated virtual environment.

A device sound module 302 generates a motion sound 322 based on the input motion task data 321 of the three industrial devices i.e. the three robots r1, r2, r3. The input motion task data 321 comprise data describing the motion task of each robot—in particular data on their source location and target location (not shown).

In embodiments, the device sound module 302 is composed by a plurality of device sound modules 352 specific for a specific type of device. Examples of device types include a robot of a given vendor, e.g. KUKA or ABB, a robot “naked” i.e. without a tool, a robot with a tool, a conveyor, a join of a robot, a turn table or other types of industrial devices which generate motion sounds. Corresponding selectable sound (sub) modules 352 are illustrated. In embodiments, these modules are modeled via a function trained via a ML algorithm.

In embodiments, the generated sound may refer to all the moving devices of the virtual environment or it may be only for a pre-selected subset of moving devices.

An operation device sound module 304 generates an operation sound 324 based on the operation type performed by the robot. Additionally, operation type can be classified in accordance with the characteristics of the material—e.g. its thickness and its material type—given that some material characteristics may have an influence on the generated operation sounds. In embodiments, corresponding operation sounds with/without material characteristics are stored and rendered retrievable. Corresponding selectable sound sub-modules 354 are illustrated.

At a sound mixer 303, the device sound for the motion task and for the process type for each device are mixed together and sent 325 to a calculator module 305.

The calculator module 305 additionally receives differential position data 326 from the simulation platform 301. The received data 326 comprise, for each robot r1, r2, r3 its corresponding distance d1, d2, d3 from the virtual receiver 316 in the virtual environment. The sound calculator 305 attenuates for each motion sound of each robot the sound received at the receiver location 316 by taking into account the distances d1, d2, d3 from the sound sources r1, r2, r3 and also obstacles (not shown).

As skilled persons easily appreciate, in embodiments, the attenuation of the motion sound is calculated dynamically by taking into account time dependent information on the moving devices and on the moving receiver.

The sound module receives data regarding device activities at defined time intervals—e.g. robotic motion tasks and robotic operations- and returns the relative sounds perceivable at a receiver location.

As the skilled person easily understand the real user 306 hears the analog converted version of the digital versions of the industrial generated sounds 327 whereby the D/A converter is in the drawing not shown.

In embodiments, the user 306 is provided with a final processed sound which realistically emulates the industrial sound experienced of a virtual user at a receiver location 316 in the virtual factory. As the skilled persons easily understand such final processed sound may preferably include a wide selection of additional noises and effects like background noises, factory noises, stereo effects, echo effects and other types of noises and effects.

In summary, in embodiments, an industrial sound generator module (not shown) may be seen as a meta-module (not shown) combining the sound generating modules 302, 303, 304, 305 with other industrial sounds and sound effects (not shown). This meta-module (not shown) receives as input data information on industrial motion devices and operations which generate dynamic sound and corresponding relative receiver location data e.g. distance from devices, orientation of the receiver and orientation of the sound source, obstacles present in the sound path and other relevant information.

In embodiments, the sound modules 302, 304 and their sub-modules 352, 354 are grouped in a sound simulator meta-module (not shown). In embodiments, any sound (sub) module 302, 304, 352, 354 or meta-module (not shown) may advantageously be provided in the cloud and/or provided as SaaS.

In embodiments, the sound simulator modules may be generated upfront and provided to the final users. In other embodiments, the users can do their ML training or generate a fix mapping by themselves.

In embodiments, the device sound simulator is for a specific type of device. In other embodiments, the device's sound simulator is generic for a generic device to fit a broad family of different type of devices.

In embodiments, the sound perceived at a receiver location, e.g. a VR user position, is generated by performing one or more of the following steps:
a. using already, prepared sound module(s)
b. for each time during simulation,
   i. sending each robot's task e.g. motion+optional operation
   ii. calculate the proper sound for each robot movement and operation
   iii. calculate the relative sound based on the mutual distance of the user from the robot
   iv. provide to a user the mix of all relative sounds.

### Exemplary Embodiment: Generating Sound of a Set of Moving Robots

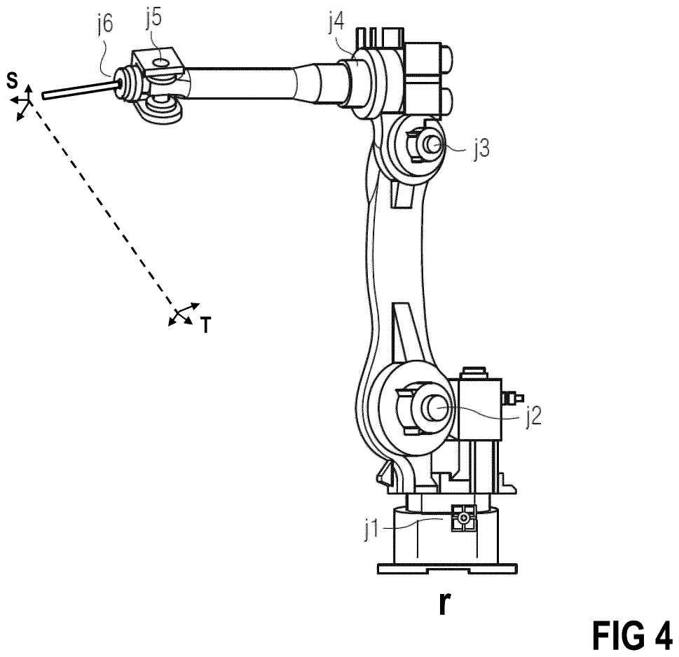

FIG. 4 schematically illustrates motion tasks data of a robot in in accordance with embodiments. The exemplary robot r with six joints (j1, j2, j3, j4, j5, j6) and a gun tool performs a robotic motion task between a source location S and a target location T.

In embodiments, motion data of the robot including data the source and target location to be inputted to a robot sound generator comprise source S and target T locations data with robot's configurations at source S and target T.

Preferably, motion S/T parameters—e.g. type of motion, speed, acceleration, zone etc—are also provided e.g. so as to realistically emulate the sound given that characteristics likes speed and acceleration have a direct impact on the robotic sound.

In embodiments, input data on S/T locations may preferably given as 3D cartesian coordinates.

In embodiments, input data on S/T locations may be given as robotic poses with joint values (j1,j2,j3,j4,j5,j6).

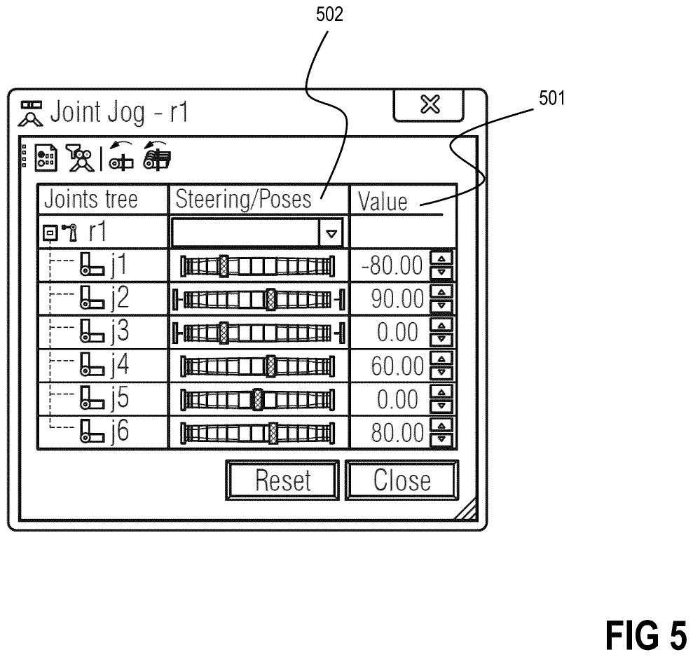

FIG. 5 schematically illustrates motion tasks data of joints of a robot r1 in accordance with embodiments. In the joint modality, a S/T location can be inputted via a “joint jog” GUI in terms of joint values numerically or via movable cursors of interconnected steering poses or via a combination thereof.

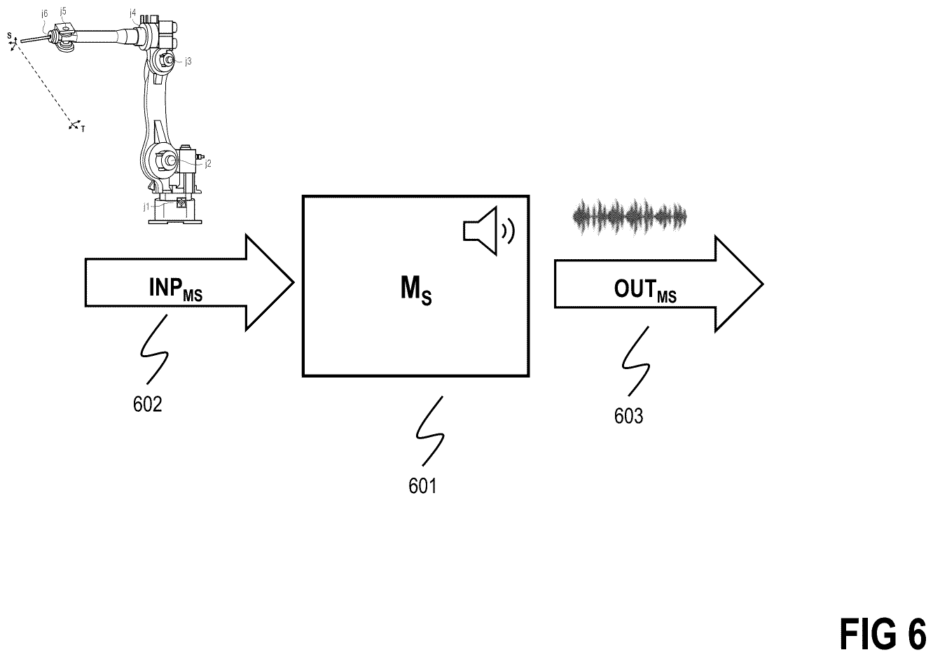

FIG. 6 schematically illustrates a block diagram for generating motion sound of a moving device in accordance with embodiments. Assume the moving device is a robot r similar as the one illustrated in FIG. 4.

In embodiments, the sound module Ms 601—a device's sound simulator—receives as input data 602 motion data on the robot's motion task (S,T) and outputs an emulation of the sound 603 generated by the device moving along the path of the motion task.

In embodiments, the robot's sound module receives as input data the robot's source and target pose at given points in time and output the robot's digital sound generated by the moving robot at the same points in time. Further sound processing includes processing the sound based on mutual position information between e.g. relative locations and relative orientations of sound source and receiver and potential obstacles present along the sound path in the factory. In embodiments, the final sound detectable at a receiver location is obtained by processing the sound e.g. by attenuating and by applying other sound effects.

In embodiments, the sound module MS 601 is modeled via a function f_{ML} trained via a ML training algorithm.

In embodiments, the device's sound simulator 601 is a module Mx obtained via a mapping or function based on stored sounds e.g. from recorded or synthetically generated sounds.

In embodiments, the output of the sound module Ms 601 is the list of sounds that the device performs along the moving—i.e. sound vs. time (e.g. msec) at sampled points of times e.g. the same sampling interval using during the ML training.

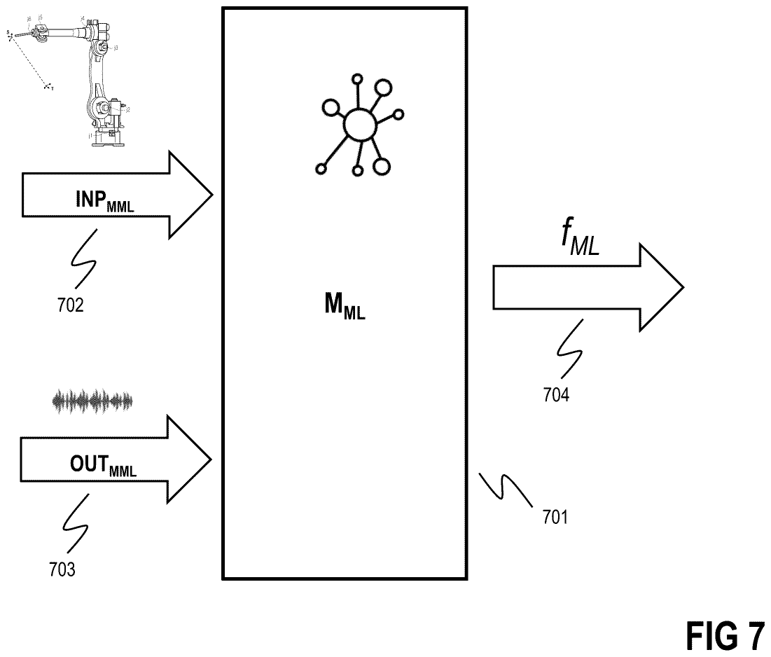

FIG. 7 schematically illustrates a block diagram for training a device sound simulator in accordance with embodiments.

The ML module MML 701 generates a trained function 704 departing from a training dataset 702, 703.

In embodiments, input training data 702 comprise a dataset on motion tasks of the device(s). Assume the device is a robot of a given type, the input training data comprise data on source and target location of the robot.

The output training dataset 703 are obtained by getting, for each input training dataset, device's sounds along the path at defined points in time—e.g. every 1 msec. In embodiments, the device's sounds are generated by digitally recording sounds of real devices, e.g. robots with or without the tool.

Embodiments of a ML training algorithm include the following steps:
receiving input training data 702 on motion task of the device;
receiving output training data 703 comprising motion sound generated by the industrial device moving between source and target (S,T) locations at defined points in time;
training the ML algorithm 701 to obtain a trained function f_{ML} 704 for modeling a device motion sound simulator.

In embodiments, the training dataset—input and output—may synthetically be prepared by generating a list of random robotic (S,T) locations pairs, by having the robot moving between the random locations pairs and by recording the sound generated by the moving robot along the path at defined time points.

In embodiments, the input training dataset comprises a set of data comprising source location S with its motion parameters, a target location T with its motion parameters plus robotic configurations at source and target locations (S,T).

In other embodiments, the motion parameters are not included and the input training dataset therefore comprises a set of data comprising source location S, a target location T plus robotic configurations at source and target locations (S,T).

In embodiments, the source and target (S, T) may be given as cartesian coordinates see Table 1 or as robotic poses see Table 2.

In Table 1 below, there is a real simple pseudo-code example where <Source location S, Target location T> where (S,T) are given as cartesian locations with configuration and motion parameters.

TABLE 1
(S,T) are given as cartesian locations

// Real example of a Weld operation of a robot moving from Source S to
target T
Source S: Config (0.−3.−2.0); Motion_type (MoveJ); SpeedData(−);
Zone_data (fine);
X(1008.9); Y(0.1); Z(1920.0); RX(0); RY(60.00); RZ(0.00);
Target T: Config (1.−3.−2.0); Motion_type (MoveJ); SpeedData(v30);
Zone_data (fine);
X(1008.9); Y(0.1); Z(1920.0); RX(0); RY(60.00); RZ(150.39);

In embodiments, robot's configurations may be given as one of the following configuration strings e.g. J5-J6-OH−, J5+J6-OH−, J5-J6-OH+, J5+J6-OH+ etc.

In Table 2 below, there is a real simple pseudo-code example where <Source robot pose Sr, Source robot pose Tr> where (Sr,Tr) are given as joint values.

TABLE 3
(Sr,Tr) are given as source and target robot's poses.

//Real example of robotic task from pose S to pose T
Pose S: (j1;j2;j3;j4;j5;j6)=(0.00;0.00;−10.00;−180.00;−10.00;−180)
Pose T: (j1;j2;j3;j4;j5;j6)=(150.39;82.87;−153.54;−180.00;−70.78;−180)

In embodiments, the output training dataset comprises the list of sounds recorded at determined time points in time from a robot moving between the list of target and source locations with/without motion parameters and with/without configurations. The recorded sounds are digitally sampled and the determined time points can be a down-sampled subset of the digital recorded sounds or can be up-sampled via reconstruction techniques.

In embodiments the robot or device is considered as a single unit and the recorded sound and the corresponding trained function refer to the whole device unit.

In other embodiments, the device is considered as a collection of moving units or elements. For example, the robot can be seen as a collection of six joints. The sounds are recorded for each separate joint for example also by using-when needed-noise cancellation techniques. In embodiments, each device's element is treated as a device and a specific sound module for the unit/joint is trained.

In summary, the kinematic device may be considered as a holistic single unit or as a combination of joints and therefore train one single module for the robot or several joint modules with input motion tasks and output sound vs. time.

As the skilled person easily appreciates the sound of the whole robot, is the accumulation of all its joint's sounds along time.

In embodiments, the robot is split in its various units e.g. in its six joints.

In Table 3 below, there is a pseudo-code example how to generate input training dataset for training a sound module for each robot's joint. For example, the joints' motion task data are given not only in terms of source locations Sj a, of target locations Tj but also in terms of middle poses Mi,j. The output training data is a list of sounds along the movement of the relevant joint.

TABLE 3
input joints' motion tasks are given as joint values robot's poses.

//Joints changing values are input of the corresponding joint ML module
For example, given input motion tasks -source, middle, target poses:
Source pose Sj: [0,0,0,0,0,0]
Middle poses Mi,j: [0,0,0,0,0,5], [4,0,0,0,0,25], [8,0,0,0,0,50]
Target pose Tj: [10,0,0,0,0,50]
Then the input motion task of the device “joint”:
[0,0,0,0,0,0]-> [0,0,0,0,0,5] are sent to the ML module for joint j5
[0,0,0,0,0,5]-> [4,0,0,0,0,25] are sent to the ML modules for joints j1, j5
[4,0,0,0,0,25] ->[8,0,0,0,0,50] are sent to the ML modules for joints j1, j5
[8,0,0,0,0,50] ->[10,0,0,0,0,50] are sent to the ML module for joint jl

In embodiments, during the training phase with training data for generating the ML trained sound simulator module, the trained function can adapt to new circumstances and can detect and extrapolate patterns.

In general, parameters of a trained function can be adapted by means of training. In particular, supervised training, semi-supervised training, unsupervised training, reinforcement learning and/or active learning can be used. Furthermore, representation learning (an alternative term is “feature learning”) can be used. In particular, the parameters of the trained functions can be adapted iteratively by several steps of training.

In particular, a trained function can comprise a neural network, a support vector machine, a decision tree and/or a Bayesian network, and/or the trained function can be based on k-means clustering, Qlearning, genetic algorithms and/or association rules.

In particular, a neural network can be a deep neural network, a convolutional neural network, or a convolutional deep neural network. Furthermore, a neural network can be an adversarial network, a deep adversarial network and/or a generative adversarial network.

In embodiments, the device sound simulator may be modeled as a set of selectable ML trained modules, it may be modeled as a set of heuristically selectable stored motion sounds and/or may be modeled as any combination thereof.

For example, in embodiments, the stored motion sounds to be heuristically selected may be part of a fixed pre-stored mapping table obtained from real or from synthetic robot's sounds.

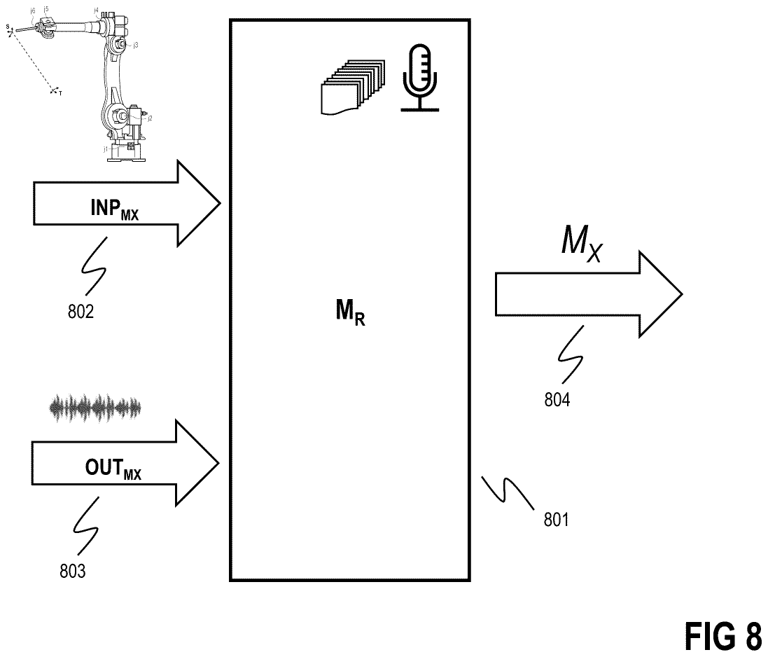

FIG. 8 schematically illustrates a block diagram for generating a sound simulator based on a fixed mapping table in accordance with embodiments.

In embodiments, input mapping motion data 802 comprise a dataset on motion tasks of the device(s). Assume the device is a robot of a given type, the input data comprise data on source and target location of the robot.

The output mapping dataset 803 are obtained by recording, for each input training dataset, device's sounds along the path at defined points in time—e.g. every 1 msec. In embodiments, the device's sounds are generated by recording sounds of real devices, e.g. robots with or without the tool.

Embodiments for generating a sound simulator 804 Mx with a pre-stored table or function include the following steps:
receiving mapping motion data 802 data comprising data on a motion task of the device with data on source and target locations (S,T);
receiving output data comprising motion sound generated by the industrial device moving between source and target (S,T) locations at defined points in time;
generating a fix mapping table or function Mx 804 for heuristically modeling a device motion sound simulator.

In embodiments, a real physical robot is provided for recording sounds for generating a specific mapping table or mapping function for associating robot's tasks with/without robot's motion parameters to robot's sounds. During usage, the stored function Mx enables to select the closest sound entry in the map for each coming robot tasks. In embodiments, it is possible to select from a close joint value, a close location value and/or a close speed a stored recorded sound. In embodiments, the robot may be naked or with a tool. In embodiments, the sound of robot's action or robot's process activities may be added.

Although exemplary embodiments of traditional robots with six joints have been described in detail, those skilled in the art are able to implement embodiments for other types of robots or for other types of moving industrial devices.

Those skilled in the art will recognize that, for simplicity and clarity, the full structure and operation of all data processing systems suitable for use with the present disclosure is not being illustrated or described herein. Instead, only so much of a data processing system as is unique to the present disclosure or necessary for an understanding of the present disclosure is illustrated and described. The remainder of the construction and operation of data processing system 100 may conform to any of the various current implementations and practices known in the art.

It is important to note that while the disclosure includes a description in the context of a fully functional system, those skilled in the art will appreciate that at least portions of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims.

1-16. (canceled)

17. A method for generating, by a data processing system, a motion sound of a moving virtual industrial device, the motion sound being detectable by a virtual receiver positioned at a location within a virtual environment of an industrial simulation having a plurality of moving virtual devices, the method comprising the following steps:
receiving data on a location of a virtual receiver;
receiving data on a virtual device for which motion sound is to be generated;
receiving input data on a motion task of the device, the motion task data of the device including data on a source location and data on a target location;
applying to the input data a device sound simulator to obtain output motion sound simulating the motion sound of the virtual device moving between the source location and the target location; and
determining the motion sound detected at the location of the receiver by processing the output motion sound with differential position data based on a mutual position between the virtual device and the virtual receiver.

18. The method according to claim 17, wherein the device sound simulator is configured to output simulation motion sound by heuristically selecting a motion sound based on a stored motion sound depending on the received input data.

19. The method according to claim 17, wherein the device sound simulator is obtained by a function trained via a machine learning algorithm.

20. The method according to claim 17, which comprises obtaining data of the receiver location via a virtual reality tool or by a selection within the virtual environment.

21. The method according to claim 17, which comprises:
receiving data on a set of moving virtual devices and input data on motion tasks of the devices, applying to the input data device sound simulators, and determining a motion sound detected at the location of the receiver by processing the output motion sound with differential position data based; and
computing a combined industrial sound at a receiver location as a combination of the set of the motion sounds of determined corresponding devices.

22. The method according to claim 19, which comprises, for the input data, selecting the data of the source S and a target T from the group consisting of:
S/T coordinate location, S/T motion parameters and S/T device's configuration;
S/T coordinate location, and S/T device's configuration;
S/T device's pose and S/T motion parameters; and
S/T device's pose.

23. The method according to claim 19, wherein the sound simulator is device-specific and the device is selected from the group consisting of:
a generic robot;
a robot of a specific type;
a robot without a tool;
a robot with a tool;
a turn table;
a conveyor;
a joint of a robot; and
a kinematic element of a kinematic device.

24. A data processing system, comprising:
a processor; and
an accessible memory, the data processing system being configured to:
receive data on a location of a virtual receiver;
receive data on a virtual device for which motion sound is to be generated;
receive input data on a motion task of the device, the motion task data of the device including data on a source location and data on a target location;
apply to the input data a device sound simulator to obtain output motion sound simulating the motion sound of the virtual device moving between the source location and the target location;
determine the motion sound detected at the location of the virtual receiver by processing the output motion sound with differential position data based on a mutual position between the virtual device and the virtual receiver.

25. The data processing system according to claim 24 wherein the device sound simulator is obtained by a function trained via a machine learning algorithm.

26. The data processing system according to claim 24, wherein, for the input data, the data of a source S and a target T are selected from the group consisting of:
S/T coordinate location, S/T motion parameters and S/T device's configuration;
S/T coordinate location, and S/T device's configuration;
S/T device's pose and S/T motion parameters; and
S/T device's pose.

27. A non-transitory computer-readable medium encoded with executable instructions that, when executed, cause one or more data processing systems to:
receive data on a location of a virtual receiver;
receive data on a virtual device for which motion sound is to be generated;
receive input data on a motion task of the device, the motion task data of the device comprising data on a source location and data on a target location;
apply to the input data a device sound simulator to obtain output motion sound simulating the motion sound of the virtual device moving between the source location and the target location; and
determine the motion sound detected at the location of the receiver by processing the output motion sound with differential position data based on a mutual position between the virtual device and the virtual receiver.

28. The non-transitory computer-readable medium according to claim 27, wherein the device sound simulator is obtained by a function trained via a machine learning algorithm.

29. The non-transitory computer-readable medium according to claim 27, wherein, for the input data, the data of a source S and a target T are selected from the group consisting of:
S/T coordinate location, S/T motion parameters and S/T device's configuration;
S/T coordinate location, and S/T device's configuration;
S/T device's pose and S/T motion parameters; and
S/T device's pose.

30. A method for providing, by a data processing system, a trained function for generating motion sound of a moving virtual industrial device, the method comprising:
receiving input training data, the input training data including data on a motion task of the device, and the motion task data of the device including data on a source location and data on a target location;
receiving output training data, the output training data including data on output motion sounds of the industrial device moving between the source location and the target location, wherein the output training data is related to the input training data;
training a function based on the input training data and the output training data via a machine learning algorithm to generate a trained function; and
providing the trained function for modeling a device sound simulator.

31. A data processing system, comprising:
a processor; and
an accessible memory, the data processing system being configured to:
receive input training data including data on a motion task of a device, the motion task data of the device including data on a source location and data on a target location;
receive output training data including data on output motion sounds of the industrial device moving between the source location and the target location, with the output training data being related to the input training data;
train a function based on the input training data and the output training data via a machine learning algorithm to generate a trained function; and
provide the trained function for modeling a device sound simulator.

32. A non-transitory computer-readable medium encoded with executable instructions that, when executed, cause one or more data processing systems to:
receive input training data, the input training data comprising data on a motion task of the device, and the motion task data of the device comprising data on a source location and data on a target location;
receive output training data, the output training data comprising data on output motion sounds of the industrial device moving between the source location and the target location, and the output training data being related to the input training data;
train a function based on the input training data and the output training data via a machine learning algorithm to generate a trained function; and
provide the trained function for modeling a device sound simulator.
